(19) United States
(12) Patent Application Publication
(10) Pub. No.: US 2006/0141717 A1
(43) Pub. Date: Jun. 29, 2006

(54) Method of forming isolation film in semiconductor device

(75) Inventor: Young Jun Kim, Seoul (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Kyoungki-do (KR)

(21) Appl. No.: 11/139,306

(22) Filed: May 27, 2005

(30) Foreign Application Priority Data
Dec. 28, 2004 (KR) 2004-114181

(51) Int. Cl. H01L 21/76

(52) U.S. Cl. 438/296; 438/424; 438/435

(57) ABSTRACT

The present invention relates to a method of forming isolation films of a semiconductor device. According to the present invention, an oxidization process is performed to oxidize inner walls of trenches in a pre-heating period where temperature is raised in order to deposit an insulating material within a chamber so as to form isolation films. Thus, a smiling phenomenon can be prevented from being generated at corners of a tunnel oxide film formed in a semiconductor substrate, and top corners of trenches can also be made round. It is thus possible to improve the reliability of a process and electrical characteristics of the device.

### BACKGROUND

1. Field of the Invention

The present invention relates to a method of forming isolation films of a semiconductor device, and more specifically, to a method of forming isolation films of a semiconductor device having a Shallow Trench Isolation (hereinafter, referred to as “STI”) structure.

2. Discussion of Related Art

An isolation film of a STI structure is formed by means of a method in which a semiconductor substrate of isolation regions is etched by a predetermined depth, thus forming trenches, and the trenches are then buried with an insulating material. If the isolation film is formed by means of this method, it is possible to prevent generation of a bird's beak. Electrical characteristics of the device is, however, greatly influenced due to generation of hump, which is caused by stress generated on the lateral sides of the isolation film.

A method of forming the isolation film of the STI structure will now be described.

FIGS. 1a to 1d are cross-sectional views for explaining a method of forming isolation films of a NAND flash memory device in the prior art.

Referring to FIG. 1a, a well (not shown) is formed in a semiconductor substrate 101. An ion implant process for controlling the threshold voltage of a transistor or a flash memory cell is then performed. A tunnel oxide film 102 and a polysilicon layer 103 for forming a floating gate are sequentially formed on the semiconductor substrate 101. A buffer oxide film 104 and a pad nitride film 105 are then sequentially formed on the polysilicon layer 103.

Referring to FIG. 1b, the pad nitride film 105, the buffer oxide film 104, the polysilicon layer 103 and the tunnel oxide film 102 of isolation regions are sequentially etched to expose the isolation regions of the semiconductor substrate 101. Thereafter, the semiconductor substrate 101 of the exposed isolation regions are etched up to a predetermined depth to form trenches 106. In this case, sidewalls of the trenches 106 are formed to have a tilt of 75 to 85 degrees.

Referring to FIG. 1c, after the trenches 106 are formed, a cleaning process is performed, and a Post Etch Treatment (PET) process is then performed under oxygen O₂ atmosphere to compensate for etch damages, which are generated on the sidewalls and bottom surfaces of the trenches 106.

Thereafter, in order to compensate for etch damages and also improve interface and adhesion characteristics with an insulating material to be formed in the trenches 106, a sidewall oxidation process is performed in a furnace under oxygen atmosphere in dry oxidization mode, thus forming an oxide film 107 on the entire structure including the trenches 106.

Referring to FIG. 1d, an insulating material layer (not shown) is formed on the entire surface so that spaces between the tunnel oxide film 102, the polysilicon layer 103 and the pad nitride film 105 and the trenches (106 of FIG. 1c) are fully buried. In this case, the insulating material layer is preferably formed using High Density Plasma (HDP) oxide. After the insulating material layer is formed, Chemical Mechanical Polishing (hereinafter, referred to as “CMP”) is implemented to strip the insulating material layer on the pad nitride film 105. An isolation film 108 consisting of the oxide film 107 and the insulating material layer is thereby formed.

In the above process, as top corners 106a of the trenches are formed to be round by means of the dry oxidization process, it is possible to prevent concentration of an electric field. However, a smiling phenomenon in which the corners of the tunnel oxide film 102 become thick is generated. This makes it difficult to form the top corners 106a of the trenches to be round.

### SUMMARY OF THE INVENTION

Accordingly, the present invention has been made in view of the above problems, and it is an object of the present invention to provide a method of forming isolation films of a semiconductor device, wherein a smiling phenomenon can be prevented from being generated at corners of a tunnel oxide film formed in a semiconductor substrate, and top corners of trenches can also be made round, thereby improving the reliability of a process and electrical characteristics of the device, in such a manner that an oxidization process is performed to oxidize inner walls of trenches in a pre-heating period where temperature is raised in order to deposit an insulating material within a chamber so as to form isolation films.

To achieve the above object, according to an aspect of the present invention, there is provided a method of forming isolation films of a semiconductor device, including the steps of providing a semiconductor substrate in which trenches are formed in isolation region, oxidizing sidewall and bottom surfaces of the trenches by means of an oxidization process within a deposition chamber while an internal temperature of the deposition chamber rises up to a deposition temperature, thus forming an oxide film, if the internal temperature of the deposition chamber rises up to the deposition temperature, depositing an insulating material within the deposition chamber to bury the trenches, and allowing the insulating material to remain only in the trenches by means of a CMP process, thus forming the isolation films.

According to an aspect of the present invention, there is provided a method of forming isolation films of a semiconductor device, including the steps of sequentially forming a tunnel oxide film, a polysilicon layer, a buffer oxide film and a pad nitride film on a semiconductor substrate, etching the pad nitride film, the buffer oxide film, the polysilicon layer and the tunnel oxide film to expose isolation regions of the semiconductor substrate, forming trenches in the isolation regions of the semiconductor substrate, oxidizing sidewall and bottom surfaces of the trenches by means of an oxidization process within a deposition chamber while an internal temperature of the deposition chamber rises up to a deposition temperature, thus forming an oxide film, if the internal temperature of the deposition chamber rises up to the deposition temperature, depositing an insulating material within the deposition chamber to bury the trenches, and allowing the insulating material to remain only in the trenches by means of a CMP process, thus forming the isolation films.

In the above, the method can further include, after the trenches are formed, the step of performing a post-etch process under oxygen atmosphere in order to mitigate etch damages generated on inner walls of the trenches.

Furthermore, the method can further include, before the oxide film is formed, the step of implementing first cleaning using a HF solution and second cleaning using NH₄OH.

The oxidization process can be performed until the internal temperature of the deposition chamber rises up to 300 to 500° C. for 5 to 150 seconds. Moreover, in the oxidization process, oxygen and helium can be supplied while the internal temperature of the deposition chamber rises, and low frequency power of 2000 to 4000 W can be applied.

The oxide film is preferably formed to a thickness of 10 to 80 Å.

The CMP process can include performing first polishing using low selectivity slurry having the same polishing rate as all materials, and performing second polishing using high selectivity slurry having a high selectivity against an insulation layer.

### BRIEF DESCRIPTION OF THE DRAWINGS

FIGS. 1a to 1d are cross-sectional views for explaining a method of forming isolation films of a NAND flash memory device in the prior art; and

FIGS. 2a to 2d are cross-sectional views for explaining a method of forming isolation films of a semiconductor device according to an embodiment of the present invention.

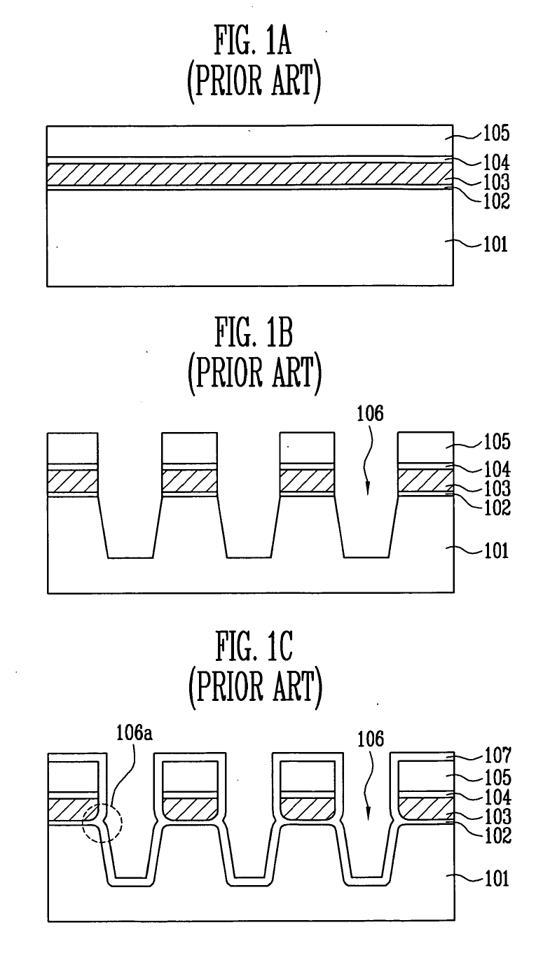

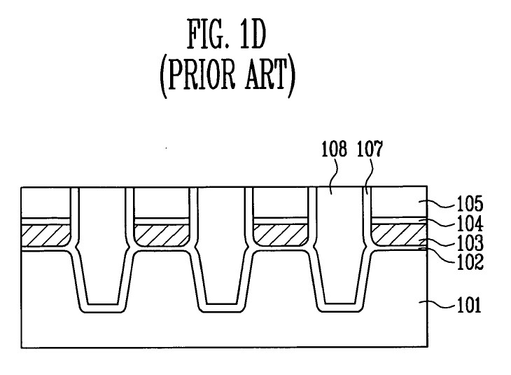

### DETAILED DESCRIPTION OF PREFERRED EMBODIMENTS

Now, the preferred embodiments according to the present invention will be described with reference to the accompanying drawings. Since preferred embodiments are provided for the purpose that the ordinary skilled in the art are able to understand the present invention, they may be modified in various manners and the scope of the present invention is not limited by the preferred embodiments described later. Meanwhile, in case where it is described that one film is “on” the other film or a semiconductor substrate, the one film may directly contact the other film or the semiconductor substrate. Or, a third film may be intervened between the one film and the other film or the semiconductor substrate. Furthermore, in the drawing, the thickness and size of each layer are exaggerated for convenience of explanation and clarity. Like reference numerals are used to identify the same or similar parts.

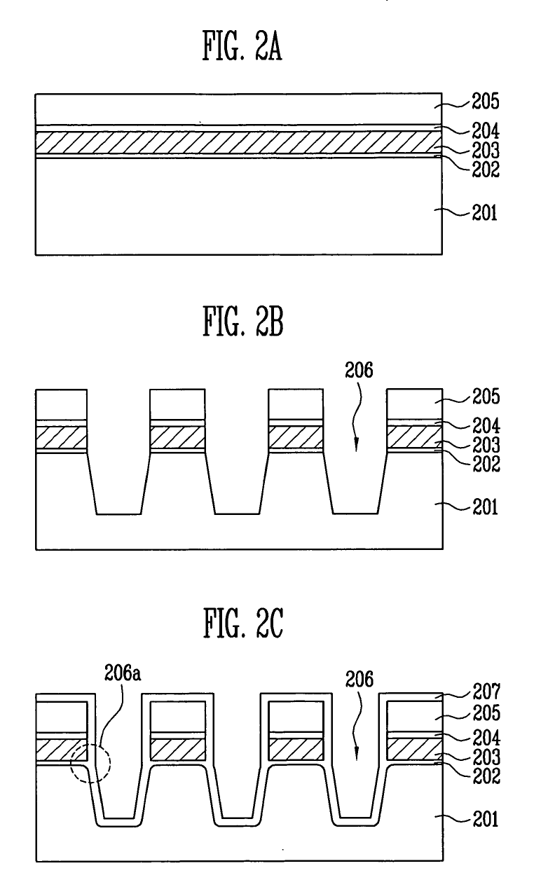

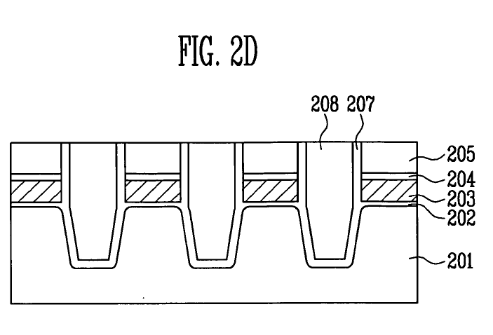

FIGS. 2a to 2d are cross-sectional views for explaining a method of forming isolation films of a semiconductor device according to an embodiment of the present invention.

Referring to FIG. 2a, a well (not shown) is formed in a semiconductor substrate 201. An ion implant process for controlling the threshold voltage of a transistor or a flash memory cell is then performed. A tunnel oxide film 202 and a polysilicon layer 203 for forming a floating gate are sequentially formed on the semiconductor substrate 201. A buffer oxide film 204 and a pad nitride film 205 are then sequentially formed on the polysilicon layer 203. In this case, the pad nitride film 205 can be formed to a thickness of 500 to 600 Å.

Meanwhile, a hard mask (not shown) can be formed on the pad nitride film 205. The hard mask can be formed to a thickness of 1000 to 2000 Å.

Referring to FIG. 2b, the pad nitride film 205, the buffer oxide film 204, the polysilicon layer 203 and the tunnel oxide film 202 of isolation regions are sequentially etched to expose the isolation region of the semiconductor substrate 201. Thereafter, the semiconductor substrate 201 of the exposed isolation regions is etched up to a predetermined depth to form trenches 206. In this case, the trenches 206 are formed to have a depth of 2000 to 15000 Å, and sidewalls of the trenches 206 are formed to have a tilt of 75 to 85 degrees.

Referring to FIG. 2c, after the trenches 206 are formed, a cleaning process is performed, and a PET process is then performed under oxygen O₂ atmosphere to compensate for etch damages, which are generated on the sidewalls and bottom surfaces of the trenches 206.

A cleaning process is then performed. In this case, the cleaning process includes performing first cleaning using a HF solution and then performing second cleaning using NH₄OH. Furthermore, the HF solution is preferably diluted with pure DI water at the ratio of 40:1 to 60:1. A total cleaning process is performed for 1 second to 1 minute.

Thereafter, in order to compensate for etch damages and also improve interface and adhesion characteristics with an insulating material to be formed in the trenches 206, an oxide film 207 is formed on the entire structure including the trenches 206 by means of an oxidization process. In this case, in the prior art, the oxidization process is formed in the furnace, whereas in the present invention, the oxidization process is carried out in a deposition chamber. This will be below described in detail.

In order to form isolation films in a subsequent process, an oxidization process for oxidizing sidewalls and bottom surfaces of the trenches 206 are performed within the deposition chamber in which the insulating material is deposited. In this case, the oxidization process is performed in a pre-heating period where a temperature within the chamber is raised up to a deposition temperature. Generally, in a temperature rising period, a nitrogen gas is injected. In order to implement the oxidization process, however, an oxygen gas and a helium gas are used instead of the nitrogen gas, wherein the flow rate of the oxygen gas and the helium gas is 100 sccm to 500 sccm. Meanwhile, in the pre-heating period, the oxidization process is performed by applying low frequency power of 2000 W to 4000 W and generating oxygen plasma, while raising the temperature within the chamber up to 300 to 500° C. for 5 to 150 seconds.

The oxide film 207 is thus formed to a thickness of 10 to 80 Å by means of the above method.

As such, if the oxidization process is performed within the deposition chamber in the pre-heating period, sidewall bottoms of the pad nitride film 203 are rarely oxidized, but the top corners 206a of the trenches are oxidized. This prevents generation of a smiling phenomenon in which the corners of the tunnel oxide film 202 become thick, and also makes the top corners 206a of the trenches rounded.

Referring to FIG. 2d, an insulating material layer (not shown) is formed on the entire surface so that spaces between the tunnel oxide film 202, the polysilicon layer 203 and the pad nitride film 205 and the trenches (206 of FIG. 2c) are fully buried. In this case, the insulating material layer can be formed consecutively with no time delay after the oxide film 207 is formed, by replacing only a supply gas. Meanwhile, the insulating material layer is preferably formed using HDP oxide, and it can be formed to a thickness of 4000 to 6000 Å.

After the insulating material layer is formed, CMP is performed to strip the insulating material layer on the pad nitride film 205. An isolation film 208 consisting of the oxide film 207 and the insulating material layer is thereby formed. In this case, the CMP process can include performing first polishing using Low Selectivity Slurry (LSS) having the same polishing rate as all materials, and performing second polishing using High Selectivity Slurry (HSS) having a high selectivity against an insulation layer.

Though not shown in the drawings, the pad nitride film 203 and the pad oxide film 202 are stripped. In this case, the pad nitride film 203 can be stripped by performing an etch process using a Buffered Oxide Etchant (BOE) solution for 200 to 400 seconds, or an etch process using a H₃PO₄ solution for 10 minutes to 30 minutes. Alternately, the pad nitride film 203 can be performed by performing the etch process using a BOE solution for 200 to 400 seconds and then performing an etch process using a H₃PO₄ solution for 10 minutes to 30 minutes.

As described above, according to a method of forming isolation films of a semiconductor device in accordance with the present invention, an oxidization process is performed to oxidize inner walls of trenches in a pre-heating period where temperature is raised in order to deposit an insulating material within a chamber so as to form isolation films. Thus, a smiling phenomenon can be prevented from being generated at corners of a tunnel oxide film formed in a semiconductor substrate, and top corners of trenches can also be made round. Accordingly, the present invention is advantageous in that it can improve the reliability of a process and electrical characteristics of the device.

Furthermore, an oxidization process and an isolation film formation process are consecutively performed in the same chamber with no time delay. It is thus possible to shorten a process time, and also to further improve interface characteristics of an oxide film and isolation films.

Although the foregoing description has been made with reference to the preferred embodiments, it is to be understood that changes and modifications of the present invention may be made by the ordinary skilled in the art without departing from the spirit and scope of the present invention and appended claims.

What is claimed is:

1. A method of forming isolation films of a semiconductor device, comprising the steps of:
providing a semiconductor substrate in which trenches are formed in isolation region;
oxidizing sidewall and bottom surfaces of the trenches by means of an oxidization process within a deposition chamber while an internal temperature of the deposition chamber rises up to a deposition temperature, thus forming an oxide film;
if the internal temperature of the deposition chamber rises up to the deposition temperature, depositing an insulating material within the deposition chamber to bury the trenches; and
allowing the insulating material to remain only in the trenches by means of a CMP process, thus forming the isolation films.

2. The method as claimed in claim 1, further comprising, after the trenches are formed, the step of performing a post-etch process under oxygen. atmosphere in order to mitigate etch damages generated on inner walls of the trenches.

3. The method as claimed in claim 1, further comprising, before the oxide film is formed, the step of implementing first cleaning using a HF solution and second cleaning using NH₄OH.

4. The method as claimed in claim 1, wherein the oxidization process is performed until the internal temperature of the deposition chamber rises up to 300° C. to 500° C.

5. The method as claimed in claim 1, wherein the oxidization process is performed for 5 to 150 seconds.

6. The method as claimed in claim 1, wherein in the oxidization process, oxygen and helium are supplied while the internal temperature of the deposition chamber rises.

7. The method as claimed in claim 1, wherein in the oxidization process, low frequency power of 2000 to 4000 W is applied.

8. The method as claimed in claim 1, wherein the oxide film is formed to a thickness of 10 to 80 Å.

9. The method as claimed in claim 1, wherein the CMP process includes performing first polishing using low selectivity slurry having the same polishing rate as all materials, and performing second polishing using high selectivity slurry having a high selectivity against an insulation layer.

10. A method of forming isolation films of a semiconductor device, comprising the steps of:
sequentially forming a tunnel oxide film, a polysilicon layer, a buffer oxide film and a pad nitride film on a semiconductor substrate;
etching the pad nitride film, the buffer oxide film, the polysilicon layer and the tunnel oxide film to expose isolation regions of the semiconductor substrate;
forming trenches in the isolation regions of the semiconductor substrate;
oxidizing sidewall and bottom surfaces of the trenches by means of an oxidization process within a deposition chamber while an internal temperature of the deposition chamber rises up to a deposition temperature, thus forming an oxide film;
if the internal temperature of the deposition chamber rises up to the deposition temperature, depositing an insulating material within the deposition chamber to bury the trenches; and
allowing the insulating material to remain only in the trenches by means of a CMP process, thus forming the isolation films.

11. The method as claimed in claim 10, further comprising, after the trenches are formed, the step of performing a post-etch process under oxygen atmosphere in order to mitigate etch damages generated on inner walls of the trenches.

12. The method as claimed in claim 10, further comprising, before the oxide film is formed, the step of implementing first cleaning using a HF solution and second cleaning using NH₄OH.

13. The method as claimed in claim 10, wherein the oxidization process is performed until the internal temperature of the deposition chamber rises up to 300° C. to 500° C.

14. The method as claimed in claim 10, wherein the oxidization process is performed for 5 to 150 seconds.

15. The method as claimed in claim 10, wherein in the oxidization process, oxygen and helium are supplied while the internal temperature of the deposition chamber rises.

16. The method as claimed in claim 10, wherein in the oxidization process, low frequency power of 2000 to 4000 W is applied.

17. The method as claimed in claim 10, wherein the oxide film is formed to a thickness of 10 to 80 Å.

18. The method as claimed in claim 10, wherein the CMP process includes performing first polishing using low selectivity slurry having the same polishing rate as all materials, and performing second polishing using high selectivity slurry having a high selectivity against an insulation layer.
